(19) United States
(12) Patent Application Publication
(10) Pub. No.: US 2012/0032141 A1
(43) Pub. Date: Feb. 9, 2012

(54) Compositions Comprising QD Sol-Gel Composites and Methods for Producing and Using the Same

(75) Inventors: Ethan Tsai, Boulder, CO (US); Arrelaine Dameron, Boulder, CO (US)

(73) Assignee: HCF PARTNERS, LP, Houston, TX (US)

(21) Appl. No.: 13/262,427

(22) PCT Filed: Apr. 2, 2009
(86) PCT No.: PCT/US09/39246

§ 371 Date: Oct. 21, 2011

(51) Int. Cl. H01L 51/52; H01L 51/56; B82Y 20/00; B82Y 40/00

(52) U.S. Cl. 257/13; 438/47; 977/950; 977/891; 257/E51.018; 257/E51.024

(57) ABSTRACT

The present invention provides OLEDs comprising cross-linked quantum dots and methods for producing and using the same.

### FIELD OF THE INVENTION

The present invention relates to OLEDs comprising cross-linked quantum dots and methods for producing and using the same.

### BACKGROUND OF THE INVENTION

A quantum dot (QD) is a nano-particulate semiconductor, whose excitons are confined in all three spatial dimensions. As a consequence of this quantum confinement, QDs possess properties that lie between those of bulk semiconductors and those of discrete molecules. QDs are unique among advanced materials in that they are size-tunable with respect to their optical and electronic properties. This provides materials that can be readily engineered, providing QDs that comprise the same elements, but which, for instance, can be made to emit light at different wavelengths by changing the size or the relative composition of the QD and provide materials that can be incorporated.

Colloidal semiconductor QDs are typically synthesized from precursor organometallic compounds dissolved in solution and is often based on a three component system comprising precursors, organic surfactants, and solvents. See, for example, Murray et al., J. Am. Chem. Soc., 1993, 115, 8706 and Peng et al., J. Am. Chem. Soc., 2001, 123, 183, which discuss preparation of CdSe QDs. These references are incorporated herein by reference in their entirety.

Much effort has been made in the development of organic light emitting diode (OLED) devices comprising QDs as the emissive layer. Currently, one of the most successful methods for producing OLED devices utilizes organic vapor deposition (OVD) processes to deposit the hole-blocking layer (HBL) and electron-transport layer (ETL) on top of the QD emissive layer. This process has been brought about because of the fragility of the QD layer, which is highly prone to perturbation when subjected to secondary solution processing steps. A “solution process” refers to a process that uses a solution of material to coat the desired layer onto a substrate or previously deposited organic layer. Indeed, it is well recognized that often an attempt to spin coat an organic layer onto a standard QD layer results in removal of the QD layer. This short coming has at least to some extent limited the attractiveness of QDs as emissive materials in OLED devices.

It is generally believed that high volume production of OLED devices will more likely be achieved using printable materials. The development of advanced printing techniques affords for high throughput and provides the potential of reduced manufacturing costs of organic electronic devices compared to OVD methods. OVD methods typically require numerous mask sets, highly expensive vacuum deposition equipment, and are generally limited to small substrate sizes.

Therefore, there is a need for other methods for forming a QD layer that can withstand subsequent solution processing steps.

### SUMMARY OF THE INVENTION

Some aspects of the invention provide organic light emitting diodes (OLEDs) comprising a cross-linked QDs. Typically, the cross-linked QDs form an emissive layer of OLEDs. In some embodiments, the QD emissive layer is homogenous. While in other embodiments, the QD emissive layer is heterogeneous. Typically, QDs are cross-linked by a linker comprising a siloxane, a plurality of hydroxy group, a plurality of carboxylic acid group, or a combination thereof. It should be appreciated that when cross-linked, the hydroxy group and the carboxlic acid group are present as an alkoxide and a carboxylate, respectively. In some embodiments, the linker comprises a siloxane, a diol, a dicarboxylic acid, or a combination thereof. Still in other embodiments, the cross-linked QDs form a solid composite.

Other aspects of the invention provide methods for producing a quantum dot (QD) emissive layer in an organic light emitting diode (OLED). Such methods typically comprise forming a layer of cross-linked QD emissive layer on a substrate. In some embodiments, the cross-linked QD emissive layer is formed by a sol-gel process. In other embodiments, the cross-linked QD emissive layer is formed by placing a solution of cross-linked QD emissive layer on the substrate. Yet in other embodiments, the cross-linked QD emissive layer comprises a linker comprising a siloxane, a plurality of hydroxy group, a plurality of carboxylic acid group, or a combination thereof. Within these embodiments, in some instances the linker comprises a siloxane, a diol, a dicarboxylic acid, or a combination thereof.

### BRIEF DESCRIPTION OF THE DRAWINGS

FIG. 1 is an electroluminescent spectra for blue and green emitting organic light emitting diode devices produced using methods of the present invention.

### DETAILED DESCRIPTION OF THE INVENTION

Some aspects of the invention methods for producing a QD layer that is stable to subsequent solution based processes. In some embodiments, methods of the invention form a QD layer using a sol-gel process. It has been found by the present inventors that forming a layer of QDs embedded into a sol-gel results in an emissive layer that is substantially impervious to subsequent solvent exposure or subsequent processes that use a solvent. Such a system provides an emissive system that can significantly reduce the cost of producing OLED devices. Often such a system also possesses improved color purity compared to conventional emissive materials.

Other aspects of the invention provide compositions comprising colloidal QDs within a sol-gel host or matrix and processes for forming such compositions.

Still other aspects of the invention provide processes for producing a QD based OLED devices comprising a QD sol-gel. In some embodiments, such processes include spin coating a solution of QD sol-gel.

Typically, the particle size of QDs is about 20 nm or less in the largest axis, and often from about 2 nm to about 20 nm. It should be appreciated, however, that the scope of the invention is not limited to any particular particle size of QDs disclosed or exemplified herein and includes all ranges of particle sizes depending on the QD based OLED devices. In some embodiments, within a particularly selected colloidal QD, the colloidal QDs are substantially mono-dispersed, that is, the particles have substantially identical size and shape.

The colloidal QDs generally possess narrow size distribution. The shape of colloidal QDs can be a sphere, a rod, a disk and the like. However, it should be appreciated that the scope of the invention is not limited to any particular colloidal QD shapes and includes all shapes of colloidal QDs.

In some embodiments, the QDs include a core of a binary semiconductor material, e.g., a core of the formula MX, where M is cadmium, zinc, mercury, aluminum, lead, tin, gallium, indium, thallium, magnesium, calcium, strontium, barium, or copper; and X is sulfur, selenium, tellurium, nitrogen, phosphorus, arsenic, or antimony.

Still in other embodiments, the colloidal QDs include a core of a ternary semiconductor material, e.g., a core of the formula M¹_{A}M²_{B}X, where each of M¹ and M² is independently cadmium, zinc, mercury, aluminum, lead, tin, gallium, indium, thallium, magnesium, calcium, strontium, barium, copper, or a mixture or an alloy thereof; and X is sulfur, selenium, tellurium, nitrogen, phosphorus, arsenic, antimony, or a mixture or an alloy thereof. Exemplary ternary semiconductors that are useful in the colloidal QDs of the invention include, but are not limited to, cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (A1N), aluminum sulfide (AlS), aluminum phosphide (AlP), aluminum arsenide (AlAs), aluminum antimonide (AlSb), lead sulfide (PbS), lead selenide (PbSe), lead telluride (PbTe), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), and thallium antimonide (TlSb).

In another embodiment, the colloidal QDs include a core of a quaternary semiconductor material, e.g., a core of the formula M¹_{A}M²_{B}M³_{C}X, where each of M¹_{A}, M²_{B} and M³_{C} is independently cadmium, zinc, mercury, aluminum, lead, tin, gallium, indium, thallium, magnesium, calcium, strontium, barium, copper, or a mixture or an alloy thereof; and X is sulfur, selenium, tellurium, nitrogen, phosphorus, arsenic, antimony, or a mixture or and alloy thereof.

Still in other embodiments, the colloidal QDs include a core of a quaternary semiconductor materials, e.g., a core of the formula MX¹_{A}X²_{B}X³_{C}, where M is cadmium, zinc, mercury, aluminum, lead, tin, gallium, indium, thallium, magnesium, calcium, strontium, barium, copper, or a mixture or an alloy thereof; and each of X¹_{A}, X²_{B} and X³_{C} is independently sulfur, selenium, tellurium, nitrogen, phosphorus, arsenic, antimony, or a mixture or an alloy thereof.

In one particular embodiment, the colloidal QDs are cadmium selenide QDs, while in another embodiment, the colloidal QDs are of cadmium, sulfide and tellurium. Yet in another embodiment, the colloidal QDs include a core of a metallic material such as gold (Au), silver (Ag), cobalt (Co), iron (Fe), nickel (Ni), copper (Cu), manganese (Mn), an alloy thereof, or an alloy of combination thereof.

In some embodiments, the core of QDs can also have an over-coating on the surface of the core. The over-coating can also be a semiconductor material, such an over-coating having a composition different than the composition of the core. The over-coating on the surface of the colloidal QDs can include materials selected from Group II-VI compounds, Group II-V compounds, Group III-VI compounds, Group III-V compounds, Group IV-VI compounds, Group I-III-VI compounds, Group II-IV-V compounds, and Group II-IV-VI compounds. Exemplary over-coating materials include, but are not limited to, CdS, CdSe, CdTe, ZnS, ZnSe, ZnTe, HgS, HgSe, HgTe, AN, AlP, AlAs, AlSb, GaAs, GaN, GaP, GaSb, InAs, InN, InP, InSb, TlAs, TlN, TlP, TlSb, PbS, PbSe, PbTe, ZnCdSe, InGaN, InGaAs, InGaP, InAlP, InAlAs, AlGaAs, AlGaP, AlInGaAs, AlInGaN, and the like, mixtures of such materials, and any other semiconductor or similar materials. The over-coating on the core material can include a single shell or can include multiple shells for selective tuning of either size or physical properties. The multiple shells can comprise different materials and may vary in their respective thicknesses.

Methods and processes of the invention include contacting a QD solution with a suitable substrate under conditions sufficient to form an emissive layer. A typical QD solution of the invention comprises a QD (e.g., a 525 and a 470 nm emitting alloy gradient QD) that is capped with pyridine, thiophene thiol, a siloxane (e.g., phenyltrimethoxy silane), or a diol (e.g., 1,3-propandiol) in chloroform. The QD solution is capable of forming a solid composite. Once formed, the composite is typically soluble in non-polar solvents such as octane. The composite solution can be deposited onto a suitably prepared substrate comprising indium tin oxide (ITO), which typically forms the anode of the resultant OLED device, and a hole injection layer (e.g., a blend of PEDOT:PSS) to yield an homogeneous emissive layer of QDs. By homogeneous, it is meant that the QDs are uniformly dispersed in the resultant product. It should be appreciated that uniform dispersion does not necessarily mean even distribution in a microscopic scale. In fact, typically the distribution of QDs in a microscopic scale may appear to be uneven. Thus, unless the context requires otherwise the terms “uniform dispersion” or “uniform distribution” are used interchangeably herein and refer to a uniform distribution of QDs in macroscopic scale. Regardless, it should be appreciated that the scope of the present invention also includes non-uniform dispersal of the colloidal QDs. In some embodiments, the solid composites can be transparent or optically clear.

Typically, useful diols comprise from two to about ten carbon atoms. Suitable saturated non-cyclic diols can often be expressed by the empirical formula CₙH₂ₙ(OH)₂, where n is from 2 to about 20, typically from 2 to about 10. It should be appreciated that useful diols can also include a cyclic moiety, an aromatic group, and/or one or more unsaturation, which can be conjugated, non-conjugated, or both. Exemplary suitable diols include, but are not limited to, 3-[4-(hydroxypropoxy)-phenoxy]-propan-l-ol; 1,2-ethandiol; 1,3-propandiol; 1,3-butandiol; 1,4-butandiol; 1,2-propandiol; 1,5-penntandiol; 1,3-hexandiol; 1,4-hexandiol; 1,5-hexandiol; 1,6-hexandiol; 1,3-heptandiol; 1,4-heptandiol; 1-5-heptandiol; 1,6-heptandiol; 1,7-heptandiol; 1,3-octandiol; 1,4-octandiol; 1,5-octandiol; 1,6-octandiol; 1,7-octandiol; 1,8-octandiol; 1,3-nonandiol; 1,4-nonandiol; 1,5-nonandiol; 1,6-nonandiol; 1,7-nonandiol; 1,8-nonandiol; 1,9-nonandiol; 1,3-decandiol; 1,4-decandiol; 1,5-decandiol; 1,6-decandiol; 1,7-decandiol; 1,8-decandiol; 1,9-decandiol; and 1,10-decandiol.

Suitable siloxanes are any that can form a sol-gel. In some particular embodiments, one or more of the following siloxanes are used:

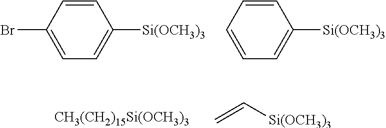

Typically, QDs of the invention are cross-linked with each other via a linker. Such cross-linking provides a QD layer that is stable to subsequent solution based processes. Depending on the number of functional groups present in the linker, a plurality of QDs can be cross-linked to provide a stable system. Often linkers comprise two or more functional groups such as hydroxyl, carboxylic acid, thiol, amine, as well as other suitable functional groups for cross-linking that are known to one skilled in the art. A linker can also have one or more different functional groups that can be used to cross-link QDs. In some embodiments, linkers comprise two or more functional groups where each is independently selected from a hydroxyl group, a thiol group, a carboxylic acid group, and an amine group. Exemplary linkers that are suitable include diol compounds such as those described herein, dicarboxylic acid compounds, dithiol compounds, diamine compounds, hydroxy amine compounds, hydroxy thiol compounds, hydroxy carboxylic acid compounds, amino acids, etc.

Additional objects, advantages, and novel features of this invention will become apparent to those skilled in the art upon examination of the following examples thereof, which are not intended to be limiting.

### EXAMPLES

### Preparation of Quantum Dot Sol-Gel

A solution of blue emitting (470 nm, photoluminescent peak emission) QDs (0.5 cm³, 40.0 mg cm⁻³ in octane, thiophene thiol capped, nominally 7.0 nm diameter, available from Crystal plex Corp. that allow gradient QDs), trimethoxyvinyl silane (6.07 μL), and propane diol (8.54 μL) in dichloromethane (CH₂Cl₂) was sonicated at 60 ° C. for 1 h and then cooled to −4° C. for 16 h. The resulting sol-gel was precipitated via the addition of a mixture of water and methanol (1:3), centrifuged, and concentrated in vacuuo. The resulting solid residue was dissolved in octane (1.0 cm³).

A solution of green emitting QDs (0.67 cm³, 30.0 mg cm⁻³ in octane, thiophene thiol capped, nominally 7.0 nm diameter, available from Crystal Plex Corp.), trimethoxyvinyl silane (6.07 μL), and propane diol (8.54 μL) in dichloromethane (CH₂Cl₂) was sonicated at 60° C. for 1 h and then cooled to −4 ° C. for 16 h. The resulting sol-gel was precipitated via the addition of a mixture of water and methanol (1:3), centrifuged, and concentrated in vacuuo. The resulting solid residue was dissolved in octane (1.0 cm³).

Organic Light Emitting Diode Device Fabrication

A multilayer OLED device was fabricated using a combination of solution processing and chemical vapor deposition (CVD). The structure of this stack was indium tin oxide (ITO), PEDOT:PSS (25.00 nm), QD sol-gel layer, 2,2′,2″-(1,3,5-benzinetriyl)-tris(1-phenyl-1-H-benzimidazole) (TPBi) (40.00 nm), LiF (1.50 nm) and a cathode comprising Al.

Briefly, ITO-coated glass was cleaned by sonication in a 2% Tergitol solution, rinsed in de-ionized (DI) water, and immersed for 10 minutes in a 70 ° C. solution of 5:1:1 DI water:ammonium hydroxide:hydrogen peroxide. The substrate was then rinsed with DI water and sonicated successively in acetone and methanol for 15 minutes each. After drying with nitrogen, the substrate was further cleaned with UV/ozone.

Spin-coating of PEDOT:PSS and the QD sol-gel layers was performed in a nitrogen-filled glove box as follows. A solution of Baytron P (0.3 cm³, 3:5) in methanol was cast onto the ITO substrate. After wetting the surface with the solution, the substrate was spun at 3000 rpm for 1 second, then at 6000 rpm for 30 seconds. The film was then annealed on a hotplate inside the glove box at 125° C. for 10 minutes. The resulting substrate was placed on the spin-coater and a solution of QD sol-gel (5.0 and 10.0 mg cm⁻³) in octane was cast onto the surface of the substrate. The substrate was spun at 3000 rpm for about one and one-half minutes, and then placed on a 125° C. hot plate for 20 min under an inert atmosphere.

The substrate with the PEDOT:PSS/QD sol-gel bilayer was then placed in a vacuum chamber, and a 40.00 nm thick layer of TPBi was deposited at a rate of about 5.0 Å s⁻¹. Film deposition was carried out at a base pressure of about 2×10⁻⁶ mbar. The chamber was then vented, and a shadow-mask for depositing patterned cathodes was placed over the device. The vacuum chamber was evacuated to a base pressure of about 2×10⁻⁶ mbar. A bi-layer of lithium fluoride and aluminum was deposited using a thermal evaporation process at a rate of about 0.1 Å s⁻¹ for LiF and about 5-25 Å s⁻¹ for Al. The resulting device was removed from the chamber and characterized under an inert atmosphere.

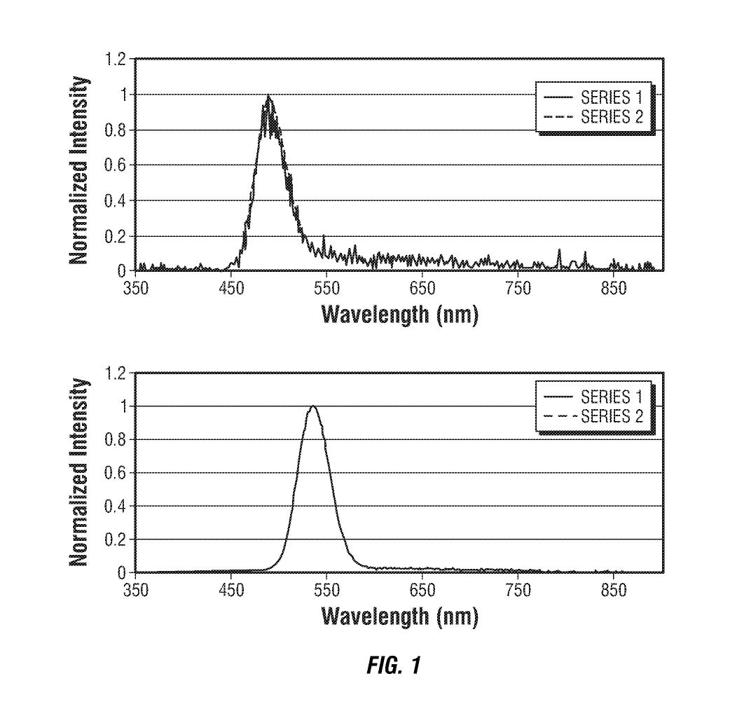

As shown in FIG. 1, the blue emitting device showed relatively pure blue electroluminescent (EL) emission, with a peak emission at 470 nm, which is in good agreement with the previously measured photoluminscent (PL) spectra. Switch on voltage was 5.0 V, with a maximum current density of 400 mA cm⁻² at 11.0 V and maximum brightness of 300 cd m² at 11.0 V.

Again referring to FIG. 1, the green emitting device showed a relatively pure green EL emission, with a peak emission at 525 nm, which is again in good agreement with the previously measured PL spectra. Switch on voltage was 3.0 V, with a maximum current density of 850 mA cm⁻² at 10.0 V and maximum brightness of 980 cd m² at 9.0 V.

The foregoing discussion of the invention has been presented for purposes of illustration and description. The foregoing is not intended to limit the invention to the form or forms disclosed herein. Although the description of the invention has included description of one or more embodiments and certain variations and modifications, other variations and modifications are within the scope of the invention, e.g., as may be within the skill and knowledge of those in the art, after understanding the present disclosure. It is intended to obtain rights which include alternative embodiments to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. An organic light emitting diode (OLED) comprising a quantum dot (QD) emissive layer, wherein said QD emissive layer comprises cross-linked QDs.

2. The OLED of claim 1, wherein said QD emissive layer is homogenous.

3. The OLED of claim 1, wherein said QDs are cross-linked by a linker comprising a siloxane, a plurality of hydroxy group, a plurality of carboxylic acid group, or a combination thereof.

4. The OLED of claim 3, wherein said QDs are cross-linked by a linker comprising a siloxane, a diol, a dicarboxylic acid, or a combination thereof.

5. The OLED of claim 1, wherein said cross-linked QDs form a solid composite.

6. A method for producing a quantum dot (QD) emissive layer in an organic light emitting diode (OLED), said method comprising forming a layer of cross-linked QD emissive layer on a substrate.

7. The method of claim 6, wherein said step of forming a cross-linked QD emissive layer comprises a sol-gel process.

8. The method of claim 6, wherein said step of forming a cross-linked QD emissive layer comprises placing a solution of cross-linked QD emissive layer on the substrate.

9. The method of claim 6, wherein the cross-linked QD emissive layer comprises a linker comprising a siloxane, a plurality of hydroxy group, a plurality of carboxylic acid group, or a combination thereof.

10. The method of claim 9, wherein the linker comprises a siloxane, a diol, a dicarboxylic acid, or a combination thereof.
